(19) United States
(12) Patent Application Publication
(10) Pub. No.: US 2008/0106839 A1
(43) Pub. Date: May 8, 2008

(54) Printed circuit board having lightning protection device

(75) Inventors: He-Kang Zhou, Shenzhen (CN); Jian-Hui Lu, Shenzhen (CN); Tong Zhou, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignees: INNOCOM TECHNOLOGY (SHENZHEN) CO., LTD.; INNOLUX DISPLAY CORP.

(21) Appl. No.: 11/982,861

(22) Filed: Nov. 5, 2007

(30) Foreign Application Priority Data
Nov. 3, 2006 (TW) 95140740

(51) Int. Cl. H02H 1/04; H05K 1/00

(52) U.S. Cl. 361/117; 174/250

(57) ABSTRACT

An exemplary printed circuit board (2) includes a substrate (21) and a printed circuit (20) formed on the substrate. The printed circuit includes a first input wire (210) and a ground wire (230). The first input wire includes at least one tip and the ground wire includes at least one tip facing the at least one tip of the first input wire. Each of the tips of the first input wire and the ground wire defines a pointed end.

### FIELD OF THE INVENTION

The present invention relates to printed circuit boards, and more particularly to a printed circuit board having lightning protection.

### GENERAL BACKGROUND

Electronic products, such as personal computers, televisions, and DVD players are widely used in modern daily life. These electronic products include power supply circuits installed therein. A typically power supply circuit includes a protection device to avoid being damaged by excess voltage or excess current. However, only a few power supply circuits also have the function of lightning protection.

FIG. 6 is an exploded, isometric view of a conventional printed circuit board with a power supply circuit installed therein. The printed circuit board 1 includes a substrate 11, and a printed circuit 10 formed on the substrate 11. The printed circuit 10 includes a live wire 110, a neutral wire 120, and a ground wire 130. The ground wire 130 includes a main body 131, and a first, a second, and a third branches 132, 133, 134. The first, second, and third branches 132, 133, 134 perpendicularly extend from the main body 131 in the same direction, and are parallel to each other. The second branch 133 is disposed at a middle portion of the main body 131. The first and third branches 132, 134 respectively include a soldering point 135, 136 in an inner side thereof.

The live wire 110 includes a main body 111 disposed between the second and third branches 133, 134. The main body 111 includes a soldering point 113 facing the soldering point 136 of the third branch 134 of the ground wire 130. The neutral wire 120 is disposed between the first and second branches 132, 133. The neutral wire 120 includes a soldering point 123 facing the soldering point 135 of the first branch 132 of the ground wire 130.

A first lightning protection element 141 is soldered between the soldering points 113, 136 of the live wire 110 and the ground wire 130. A second lightning protection element 142 is soldered between the soldering points 123, 135 of the neutral wire 120 and the ground wire 130. The first and second lightning protection elements 141, 142 are voltage dependent resistors (VDR).

A voltage dependent resistor has the following characteristics. When voltage applied to the voltage dependent resistor is low, typically below a threshold value, the voltage dependent resistor functions as an insulating resistor, and there is no current flowing therethrough. When voltage applied to the voltage dependent resistor is high, typically in excess of the threshold value, the resistance of the voltage dependent resistor decreases sharply. A large pulse current flows through the voltage dependent resistor, and the voltage dependent resistor breaks down.

In normal use of the printed circuit board 1, there is no voltage applied to the lightning protection element 141, 142, and there is no current flowing though the soldering points 113 and 136, or 123 and 135. When lightning voltage is applied to the printed circuit board 1 via the live wire 110 or the neutral wire 120, the lightning voltage is correspondingly applied to the first or second lightning protection element 141, 142. The applied lightning voltage is in excess of the threshold value of the first or second lightning protection element 141, 142. Thereby the first or second lightning protection element 141, 142 is broken down. A large pulse current generated by the lightning flows to the ground wire 130 via the first or second lightning protection elements 141, 142. Thereby, the printed circuit board 1 avoids being damaged by the lightning voltage.

The printed circuit board 1 uses the voltage dependent resistors as the first and second lightning protection elements 141, 142. However, the voltage dependent resistors are rather expensive, and a process of soldering is needed to install the voltage dependent resistors. Thus the cost of the printed circuit board 1 is correspondingly high.

What is needed, therefore, is a printed circuit board that can overcome the above-described deficiencies.

### SUMMARY

In one aspect, a printed circuit board includes a substrate, and a printed circuit formed on the substrate. The printed circuit includes a first input wire and a ground wire. The first input wire includes at least one tip and the ground wire includes at least one tip facing the at least one tip of the first input wire. Each of the tips of the first input wire and the ground wire defines a pointed end.

In another aspect, a printed circuit board includes a substrate, and a printed circuit formed on the substrate. The printed circuit includes a first input wire and a ground wire. The first input wire includes at least one tip and the ground wire includes at least one tip facing the at least one tip of the first input wire. The ground wire and two tips that faced each other define a lightning protection element.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is an exploded, isometric view of a printed circuit board according to a first embodiment of the present invention.

FIG. 2 is an exploded, isometric view of a printed circuit board according to a second embodiment of the present invention.

FIG. 3 is an exploded, isometric view of a printed circuit board according to a third embodiment of the present invention.

FIG. 4 is an exploded, isometric view of a printed circuit board according to a fourth embodiment of the present invention.

FIG. 5 is an exploded, isometric view of a printed circuit board according to a fifth embodiment of the present invention.

FIG. 6 is an exploded, isometric view of a conventional printed circuit board with a power supply circuit installed therein.

### DETAILED DESCRIPTION OF PREFERRED EMBODIMENTS

Reference will now be made to the drawings to describe preferred and exemplary embodiments in detail.

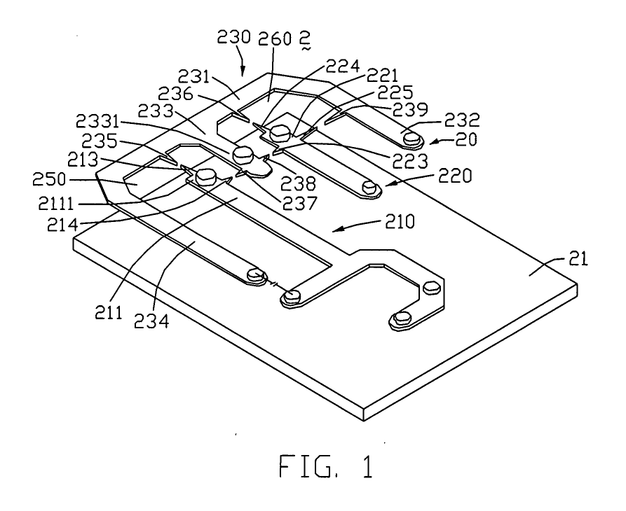

FIG. 1 is an exploded, isometric view of a printed circuit board 2 according to a first embodiment of the present invention. The printed circuit board 2 includes a substrate 21, and a printed circuit 20 formed on the substrate 21. The printed circuit 20 includes a first input wire 210, a second input wire 220, and a ground wire 230. The first input wire 210 may be a live wire, and the second input wire 220 may be a neutral wire. The ground wire 230 includes a main body 231, and a first, a second, and a third branches 232, 233, 234.

The first, second, and third branches 232, 233, 234 perpendicularly extend from the main body 231 in the same direction, and are parallel to each other. The second branch 233 is disposed at a middle portion of the main body 231. The second and third branches 233, 234 together with corresponding portions of the main body 231 cooperatively form a first space 250. The second and first branches 233 together with a corresponding portion of the main body 231 cooperatively form a second space 260.

The main body 231 includes a first and a second protrusions 235, 236 protruding into the first and second spaces 250, 260, respectively. The first branch 232 includes a third protrusion 239 protruding into the second space 260. The second branch 233 includes a fourth and a fifth protrusions 237, 238 protruding into the first and second spaces 250, 260, respectively.

The second input wire 220 is disposed between the first and second branches 232, 233 in the second space 260. The second input wire 220 includes an input terminal 221 adjacent to the main body 231 of the ground wire 230 for receiving an input alternating voltage. The input terminal 221 includes a sixth, a seventh, and an eighth protrusions 223, 224, 225 facing the fifth, second, and third protrusions 238, 236, 239, respectively.

The first input wire 210 includes a main body 211 disposed between the second and third branches 233, 234 in the first space 250. The first input wire 210 includes an input terminal 2111 adjacent to the main body 231 of the ground wire 230 for receiving another input alternating voltage. The input terminal 2111 includes a ninth and a tenth protrusions 213, 214 facing the first and fourth protrusions 235, 237, respectively.

Each of the protrusions 235, 236, 239, 237, 238, 223, 224, 225, 213, 214 has a tip (not labeled) which defines a pointed end. The distance between the tips of each two protrusions that face each other is about 3.2 millimeters (mm). In the illustrated embodiment, each of the protrusions 235, 236, 239, 237, 238, 223, 224, 225, 213, 214 has a triangular shape.

In normal use of the printed circuit board 2, alternating voltages are applied to the input terminals 2111, 221 of the first and second input wires 210, 220. The alternating voltages are not large, and no current passes between any two protrusions that face each other.

When a lightning voltage is applied to the printed circuit board 2 via the first input wire 210, a large pulse current generated by the lightning flows to the ground wire 230 between the first and ninth protrusions 235, 213, and between the fourth and tenth protrusions 237, 214. When a lightning voltage is applied to the printed circuit board 2 via the second input wire 220, the large pulse current generated by the lightning flows to the ground wire 230 between the second and seventh protrusions 236, 224, between the third and eighth protrusions 239, 225, and between the fifth and sixth protrusions 238, 223. Thus, the printed circuit board 2 avoids being damaged by lightning.

In summary, the protrusions 235, 236, 239, 237, 238, 223, 224, 225, 213, 214 are arranged at the first input wire 210, the second input wire 220, and the ground wire 230 to prevent the printed circuit board 2 from being damaged by lightning voltage. Therefore, unlike in a conventional circuit board, lightning protection elements such as voltage dependent resistors are not needed in the printed circuit board 2. In addition, the protrusions are integrally formed together with the respective first input wire 210, second input wire 220, and ground wire 230. That is, unlike with a conventional circuit board, there is no need for a process of soldering lightning protection elements in the printed circuit board 2. Thus the printed circuit board 2 is inexpensive.

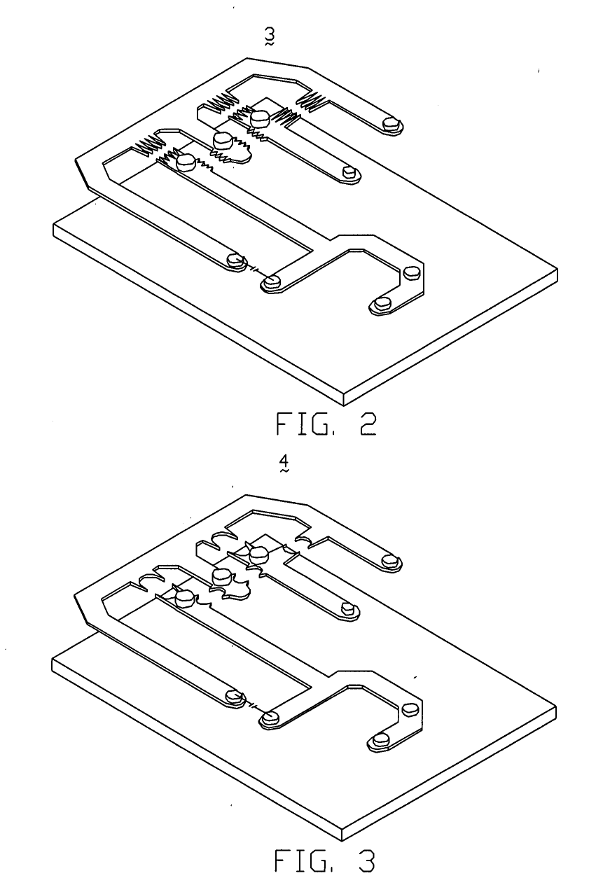

FIG. 2 is an exploded, isometric view of a printed circuit board 3 according to a second embodiment of the present invention. The printed circuit board 3 has a structure similar to that of the printed circuit board 2. However, each of protrusions (not labeled) of the printed, circuit board 3 has a sawtooth shape. Thereby, each of the protrusions has a plurality of tips.

FIG. 3 is an exploded, isometric view of a printed circuit board 4 according to a third embodiment of the present invention. The printed circuit board 4 has a structure similar to that of the printed circuit board 2. However, each of protrusions (not labeled) of the printed circuit board 4 includes two tips. The two tips cooperatively form an arc-shaped edge of the protrusion therebetween. In alternative embodiments, the two tips can cooperatively form a semicircular edge of the protrusion therebetween, or an arch-shaped edge of the protrusion therebetween.

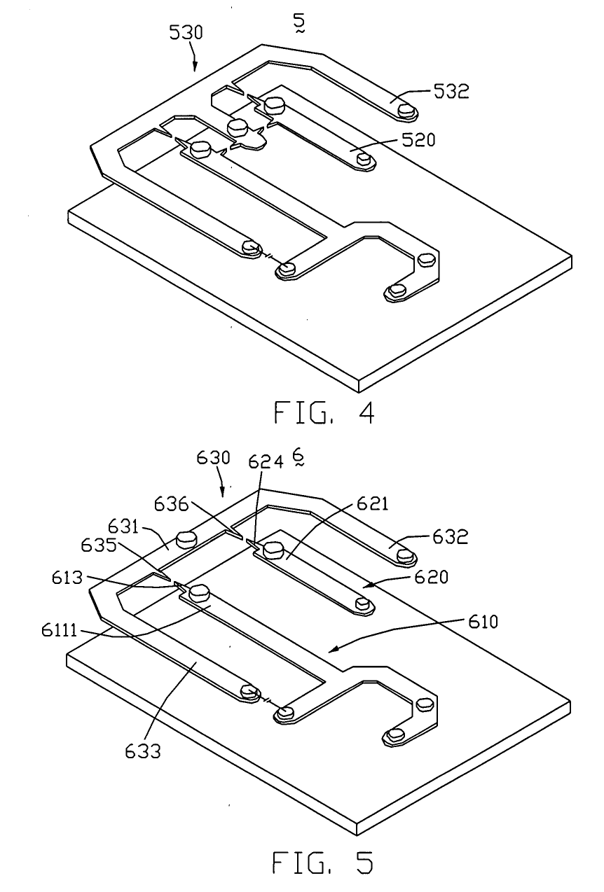

FIG. 4 is an exploded, isometric view of a printed circuit board 5 according to a fourth embodiment of the present invention. The printed circuit board 5 has a structure similar to that of the printed circuit board 2. However, there is no protrusion disposed between a first branch 532 of a ground wire 530 and a second input wire 520 of the printed circuit board 5.

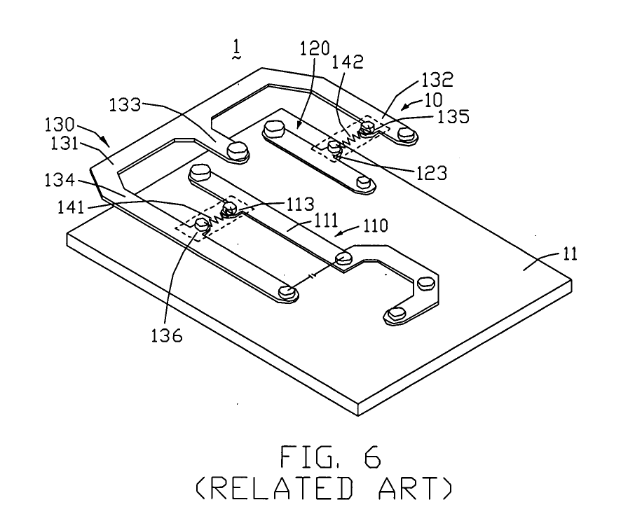

FIG. 5 is an exploded, isometric view of a printed circuit board 6 according to a fifth embodiment of the present invention. The printed circuit board 6 has a structure similar to that of the printed circuit board 2. However, an ground wire 630 includes a main body 631, and a first and a second branches 632, 633. The first and second branches 632, 633 perpendicularly extend from the main body 631 in the same direction, and are parallel to each other. A first input wire 610 and a second input wire 620 are disposed between the first and second branches 632, 633.

The main body 631 of the ground wire 630 includes two protrusions 635, 636. Terminals of the first input wire 610 and the second input wire 620 that are adjacent to the main body 631 of the ground wire 630 respectively include a protrusion 613, 624. The protrusions 613, 624 face the protrusions 635, 636 of the ground wire 630, respectively. Each of the protrusions 635, 636, 613, 624 has a tip, which defines a pointed end.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board, comprising:
a substrate; and
a printed circuit formed on the substrate, the printed circuit comprising a first input wire having at least one tip and an ground wire having at least one tip facing the at least one tip of the first input wire;
wherein each of the tips of the first input wire and the ground wire defines a pointed end.

2. The printed circuit board as claimed in claim 1, further comprising a second input wire having at least one tip, the ground wire having at least one tip facing to the at least one tip of the second input wire, each of the tips of the second input wire and the ground wire defining a pointed end.

3. The printed circuit board as claimed in claim 2, wherein a distance between each two tips that face each other is approximately 3.2 millimeters.

4. The printed circuit board as claimed in claim 2, wherein the first input wire comprises at least one protrusion, the ground wire comprises at least one protrusion facing to the at least one protrusion of the first input wire, the tips of the first input wire and the ground wire are formed at the protrusions.

5. The printed circuit board as claimed in claim 4, wherein the second input wire comprises at least one protrusion, the ground wire comprises at least one protrusion facing to the at least one protrusion of the second input wire, the tips of the first second input wire and the ground wire are formed at the protrusions.

6. The printed circuit board as claimed in claim 5, wherein each of the protrusions of the first input wire, the second input wire, and the ground wire generally has a triangular shape.

7. The printed circuit board as claimed in claim 5, wherein each of the protrusions of the first input wire, the second input wire, and the ground wire defines two tips, the two tips generally define an arc-shaped groove therebetween.

8. The printed circuit board as claimed in claim 5, wherein each of the protrusions of the first input wire, the second input wire, and the ground wire generally has a sawtooth shape.

9. The printed circuit board as claimed in claim 2, wherein the ground wire comprises a main body, a first branch, and a second branch, the first and second branches extend from the main body of the ground wire in a same direction, the tips of the ground wire are formed at the main body, the first branch, and the second branch.

10. The printed circuit board as claimed in claim 9, wherein the ground wire further comprises a third branch disposed in the middle of the main body.

11. The printed circuit board as claimed in claim 10, wherein the first, second, and third branches are parallel to each other.

12. The printed circuit board as claimed in claim 10, wherein the first input wire is disposed between the second and third branches of the ground wire.

13. The printed circuit board as claimed in claim 10, wherein the second input wire is disposed between the first and third branches of the ground wire.

14. The printed circuit board as claimed in claim 2, wherein the first input wire is a live wire and the second input wire is a neutral wire.

15. The printed circuit board as claimed in claim 2, wherein the first input wire is a neutral wire and the second input wire is a live wire.

16. A printed circuit board, comprising:
a substrate; and
a printed circuit formed on the substrate, the printed circuit comprising a first input wire having at least one tip and a ground wire having at least one tip facing the at least one tip of the first input wire;
wherein the ground wire and the two tips that face each other cooperatively define a lightning protection element.

17. The printed circuit board as claimed in claim 16, further comprising a second input wire having at least one tip, the ground wire having at least one tip facing to the at least one tip of the second input wire, two tips that faced to each other define another lightning protection element.

18. The printed circuit board as claimed in claim 17, wherein a distance between each two tips that face each other is approximately 3.2 millimeters.

19. The printed circuit board as claimed in claim 17, wherein each of the tips of the first input wire, the second input wire, and the ground wire defines a pointed end.

20. A printed circuit board, comprising:
a substrate; and
a printed circuit formed on the substrate, the printed circuit comprising a first input wire having a plurality of first tips and a ground wire having a plurality of second tips arranged close to the corresponding first tips, respectively;
wherein the ground wire and the first and second tips cooperatively define a lightning protection element.
